(19) United States
(12) Patent Application Publication
(10) Pub. No.: US 2025/0015023 A1
(43) Pub. Date: Jan. 9, 2025

(54) Semiconductor structure and forming method thereof

(71) Applicant: UNITED MICROELECTRONICS CORP., Hsin-Chu City (TW)

(72) Inventors: Chiu-Jung Chiu, Tainan City (TW); Chung-Hsing Kuo, Taipei City (TW); Chun-Ting Yeh, Taipei City (TW); Chuan-Lan Lin, Chiayi City (TW); Yu-Ping Wang, Hsinchu City (TW); Yu-Chun Chen, Kaohsiung City (TW)

(73) Assignee: UNITED MICROELECTRONICS CORP., Hsin-Chu City (TW)

(21) Appl. No.: 18/229,640

(22) Filed: Aug. 2, 2023

(30) Foreign Application Priority Data
Jul. 6, 2023 (TW) 112125241

(51) Int. Cl. H01L 23/00; H01L 23/522; H01L 23/528; H01L 23/532

(52) U.S. Cl. CPC H01L 24/05; H01L 23/5226; H01L 23/5283; H01L 23/53223; H01L 24/80; H01L 2224/02373; H01L 2224/05573; H01L 2224/05624; H01L 2224/05647; H01L 2224/80895

(57) ABSTRACT

The invention provides a semiconductor structure, which comprises a plurality of metal circuit layers stacked with each other, the multi-layer metal circuit layer comprises an aluminum circuit layer which is located at the position closest to a surface among the plurality of circuit layers, the material of the aluminum circuit layer is made of aluminum, and the aluminum circuit layer comprises a concave portion.

### BACKGROUND OF THE INVENTION

### 1. Field of the Invention

The present invention relates to the field of semiconductors, in particular to a semiconductor structure comprising a metal circuit layer and a hybrid bond contact.

### 2. Description of the Prior Art

In the conventional technologies, common chip packaging methods include chip on film (COF), chip on glass (COG) or chip on plastic (COP).

With the development of technology, the size of semiconductor devices is gradually shrinking and the fineness is getting higher and higher, and the above packaging methods are gradually insufficient to meet the needs of current technology. It is necessary to develop packaging methods with higher precision and smaller size to meet the actual use requirements.

### SUMMARY OF THE INVENTION

The invention provides a semiconductor structure, which comprises a plurality of metal circuit layers stacked with each other, the plurality of metal circuit layers comprises an aluminum circuit layer which is located at the position closest to a surface among the plurality of circuit layers, wherein the material of the aluminum circuit layer is made of aluminum, and the aluminum circuit layer comprises a concave portion.

The invention also provides a method for forming a semiconductor structure, which comprises forming a plurality of metal circuit layers stacked with each other, wherein the plurality of metal circuit layers comprise an aluminum circuit layer, which is located at the position closest to a surface among the plurality of circuit layers, wherein the material of the aluminum circuit layer is made of aluminum, and the aluminum circuit layer comprises a concave portion.

The present invention is characterized by providing a semiconductor structure including metal circuit layers and hybrid bond contact, only the metal circuit layer closest to the hybrid bond contacts (that is, the top metal circuit layer except the hybrid bond contacts) is made of aluminum, and the remaining metal circuit layers, contact posts and the hybrid bond contacts are all made of copper. Because aluminum is less prone to oxidation reaction when it exposed in the air, it can be tested after the aluminum metal layer is completed to ensure that the electrical properties of the multi-layer metal circuit layer meet the specifications, and then continue to make hybrid bond contacts. In addition, the aluminum circuit layer of the invention has a special cross-sectional shape. The structure of the present invention can be applied to a test key region in a semiconductor element.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1 to 3 show partial structural schematic diagrams of a semiconductor structure of the present invention.

### DETAILED DESCRIPTION

To provide a better understanding of the present invention to users skilled in the technology of the present invention, preferred embodiments are detailed as follows. The preferred embodiments of the present invention are illustrated in the accompanying drawings with numbered elements to clarify the contents and the effects to be achieved.

Please note that the figures are only for illustration and the figures may not be to scale. The scale may be further modified according to different design considerations. When referring to the words “up” or “down” that describe the relationship between components in the text, it is well known in the art and should be clearly understood that these words refer to relative positions that can be inverted to obtain a similar structure, and these structures should therefore not be precluded from the scope of the claims in the present invention.

Please refer to FIG. 1, which shows a partial structural schematic diagram of the semiconductor structure of the present invention. As shown in FIG. 1, in a dielectric layer of a semiconductor structure, a plurality of metal layers are formed. The metal layer also includes a metal circuit layer extending along the horizontal direction and a contact post penetrating through the dielectric layer along the vertical direction. In FIG. 1, a plurality of metal layers are labeled as a metal circuit layer M11, a contact post V10 and a metal circuit layer M10. It is worth noting that there may be other contact posts or metal circuit layers under the metal circuit layer M10. In addition, different metal circuit layers and different contact posts may be located in different dielectric layers, and the material of the dielectric layer may include insulating materials such as silicon nitride, silicon oxide or silicon oxynitride, but in FIG. 1, for the sake of simplicity, the dielectric layer and other contact posts or metal circuit layers below the metal circuit layer M10 are omitted. Generally speaking, the numbers of the metal circuit layer M11, the metal circuit layer M10 and the contact post V10 here indicate which metal circuit layer or contact post is stacked from bottom to top in the semiconductor structure. For example, the metal circuit layer M11 is the 11th metal circuit layer stacked in the semiconductor structure. However, it can be understood that the number of stacked metal circuit layers or contact posts may be different with different semiconductor structures. FIG. 1 is only one example, and the actual number of stacked metal circuit layers or contact posts may change as required. In other words, the uppermost metal circuit layer shown in FIG. 1 may be M11, or in other embodiments, it may be M8, M9, M12, M15 or Mx (where x represents other positive integers), all of which are within the scope of the present invention.

The material of the metal circuit layer or contact post described in FIG. 1 above is preferably made of copper. Copper has the advantage of good electrical conductivity, so it is often used to make circuit layers in semiconductor structures. However, when copper is exposed to air, it is easy to oxidize and the conductivity is obviously reduced, so it is better to make it in oxygen-free environment in the above process. But in this way, if the applicant wants to test the quality of metal circuit layer, it will increase the difficulty of testing.

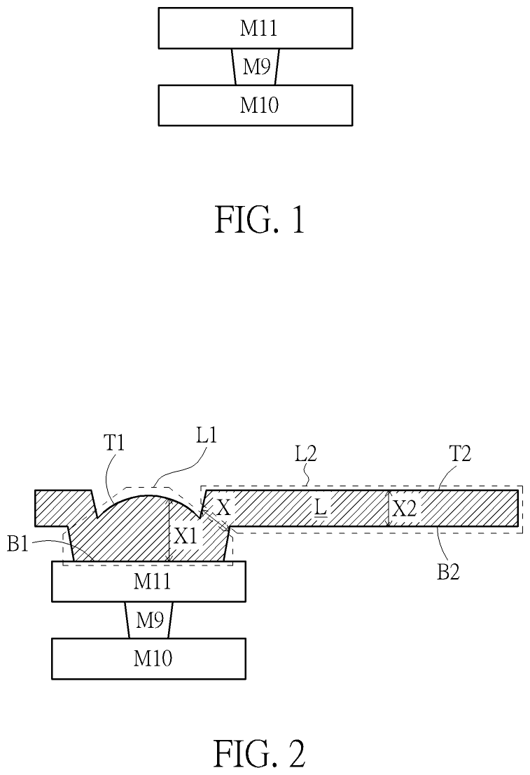

As shown in FIG. 2, in the present invention, an aluminum circuit layer L is formed on the surface of the metal circuit layer M11, and the material of the aluminum circuit layer L is made of aluminum. Seen from the sectional view, the aluminum circuit layer L has a special shape. Specifically, the aluminum circuit layer L includes a first portion L1 and a second portion L2. In this embodiment, the first portion L1 has a function similar to the above-mentioned contact post V10, which is electrically connected to the lower metal circuit layer M11, penetrates the dielectric layer (not shown) and contacts the upper second portion L2. It is worth noting that the shape of the first portion L1 is different from that of the contact post V10. For example, the width of the first portion L1 is preferably larger than the width of other contact posts (such as the contact post V10), and the first portion L1 has a concave portion in a cross-sectional view, and the cross-sectional shape is similar to a “U” shape. In this embodiment, the first portion L1 and the second portion L2 are directly connected, and the first portion L1 includes the top surface T1, and the second portion L2 also includes the top surface T2. The bottom surface B1 of the first portion L1 is lower than the bottom surface B2 of the second portion L2, and the bottom surface B1 of the first portion L1 contacts and covers the top surface of the metal circuit layer M11. It is also worth noting that the top surface T1 of the first portion L1 is a convex top surface, the bottom surface B1 of the first portion L1 is a flat surface, while the top surface T2 of the second portion L2 is a flat surface, and the bottom surface B2 of the second portion L2 is also flat. The height of the top surface T1 is preferably lower than the height of the top surface T2. In some embodiments, the highest point of the top surface T1 of the first portion L1 is higher than the bottom surface B2 of the second portion L2. In addition, the interface between the first portion L1 and the second portion L2, that is, the sidewall portion of the first portion L1, has a thickness X smaller than the thickness X1 of the first portion L1 or the thickness X2 of the second portion L2.

The aluminum circuit layer L mentioned here can be regarded as the topmost metal circuit layer among the multi-layer metal circuit layers, that is to say, the semiconductor structure contains multi-layer metal circuit layers and contact posts for connecting different electronic components. Except for the top aluminum circuit layer L, the materials of the other lower metal circuit layers and contact posts are preferably copper. That is to say, after the fabrication of multi-layer metal circuit layers is completed, only the topmost aluminum circuit layer L is exposed to the air, while other metal circuit layers or contact posts will be covered or buried in the dielectric layer without direct contact with the air.

According to the invention, after the completion of the aluminum circuit layer L and before the formation of subsequent devices, an electrical test step can be performed on the multi-layer metal circuit layer. As mentioned above, since aluminum is less likely to react with air, it is more suitable to be exposed to air for electrical test than copper. For example, the content of electrical testing includes testing whether there is an open circuit or resistance test, etc. If the test results meet the predetermined specifications, the next step can be continued. On the other hand, if the test results do not meet the specifications, it means that the multi-layer metal circuit layers have some problems and are damaged. At this time, the process adjustment step may be carried out to find out the process or parameters with problems, and the damaged semiconductor structure may be discarded or recycled.

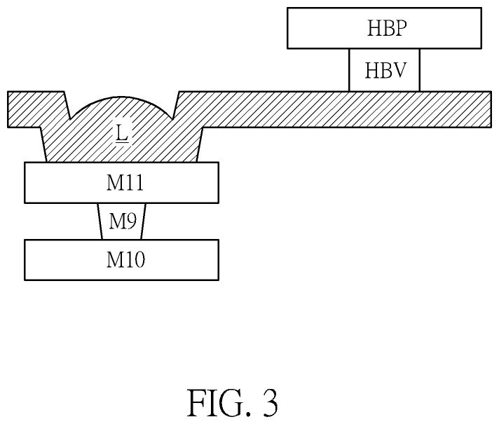

If the above-mentioned electrical test steps pass, as shown in FIG. 3, a hybrid bond contact is formed on the aluminum circuit layer L, wherein the hybrid bond contact includes a hybrid bond via HBV and a hybrid bond pad HBP, and the hybrid bond via HBV directly contacts the second portion L2 of the aluminum circuit layer L. Both the hybrid bond via HBV and the hybrid bond pad HBP are preferably made of copper, and the area of the hybrid bond pad HBP is preferably larger than that of the hybrid bond via HBV, and the hybrid bond pad HBP and the first portion of the aluminum circuit layer L. In this embodiment, the hybrid bond via HBV is used to connect the hybrid bond pad HBP with the aluminum circuit layer L, and the hybrid bond pad HBP is used to connect another semiconductor structure, such as another semiconductor structure that also includes a plurality of circuit layers and contact pads, so that the contact pads of the two semiconductor structures are directly contacted and connected in a face-to-face manner. The above packaging method is also called hybrid bonding. Compared with other kinds of packaging methods in semiconductor process (such as solder packaging, wiring packaging, etc.), hybrid bonding can effectively improve the density of components and reduce the volume of components.

Based on the above description and drawings, the present invention provides a semiconductor structure, which comprises a plurality of metal circuit layers (for example, the aluminum circuit layer L, the metal circuit layer M11, the contact post V10, the metal circuit layer M10, etc. in FIG. 2) stacked with each other, wherein the multi-layer metal circuit layer comprises an aluminum circuit layer L which is located at the position closest to a surface among the plurality of circuit layers, wherein the material of the aluminum circuit layer L is made of aluminum, and the aluminum circuit layer L comprises a concave portion (i.e., the first portion L1).

In some embodiments of the present invention, the aluminum circuit layer L includes a first portion L1 and a second portion L2, wherein a bottom B1 of the first portion L1 is lower than a bottom B2 of the second portion L2, and the concave portion is located in the first portion L1.

In some embodiments of the present invention, the first portion L1 has a U-shaped cross section.

In some embodiments of the present invention, a central portion of the first portion L1 has a convex top surface T1 and a flat bottom surface B1.

In some embodiments of the present invention, the second portion L2 has a flat bottom B1 and a flat top T2.

In some embodiments of the present invention, a hybrid bond contact (i.e., a hybrid bond via HBV and a hybrid bond pad HBP) is located on the second portion L2 of the aluminum circuit layer L, wherein the material of the hybrid bond contact is made of copper.

In some embodiments of the present invention, the hybrid bond via HBV and the hybrid bond pad HBP are stacked from bottom to top, and an area of the hybrid bond pad HBP is larger than an area of the hybrid bond via HBV.

In some embodiments of the present invention, among the plurality of metal circuit layers, other metal circuit layers (i.e., the metal circuit layer M11, the contact post V10, the metal circuit layer M10, etc.) located below aluminum circuit layer L are made of copper.

The present invention also provides a method for forming a semiconductor structure, which comprises forming a plurality of metal circuit layers (such as the aluminum circuit layer L, the metal circuit layer M11, the contact post V10, the metal circuit layer M10 in FIG. 2, etc.) stacked with each other, wherein the multi-layer metal circuit layer comprises an aluminum circuit layer L located at the position closest to a surface among the plurality of circuit layers, wherein the material of the aluminum circuit layer L is made of aluminum, and the aluminum circuit layer L comprises a concave portion (i.e. the first portion L1).

In some embodiments of the present invention, after the aluminum circuit layer is formed, the aluminum circuit layer L is located on a top surface of the semiconductor structure, and further includes a test step to test whether an electrical value of the plurality of metal circuit layer meets a preset requirement.

In some embodiments of the present invention, if the electrical values of the multi-layer metal circuit layers meet the preset requirements, hybrid bond contacts are continuously formed.

In some embodiments of the present invention, if the electrical values of the plurality of metal circuit layers do not meet the preset requirements, the semiconductor structure is discarded and a process adjustment step is performed.

The present invention is characterized by providing a semiconductor structure including metal circuit layers and hybrid bond contact, only the metal circuit layer closest to the hybrid bond contacts (that is, the top metal circuit layer except the hybrid bond contacts) is made of aluminum, and the remaining metal circuit layers, contact posts and the hybrid bond contacts are all made of copper. Because aluminum is less prone to oxidation reaction when it exposed in the air, it can be tested after the aluminum metal layer is completed to ensure that the electrical properties of the multi-layer metal circuit layer meet the specifications, and then continue to make hybrid bond contacts. In addition, the aluminum circuit layer of the invention has a special cross-sectional shape. The structure of the present invention can be applied to a test key region in a semiconductor element.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor structure comprising:
a plurality of metal circuit layers stacked with each other, wherein the plurality of metal circuit layers comprise an aluminum circuit layer which is located at the position closest to a surface among the plurality of circuit layers, wherein the material of the aluminum circuit layer is made of aluminum, and the aluminum circuit layer comprises a concave portion.

2. The semiconductor structure according to claim 1, wherein the aluminum circuit layer comprises a first portion and a second portion, wherein a bottom surface of the first portion is lower than a bottom surface of the second portion, and the concave portion is located in the first portion.

3. The semiconductor structure according to claim 2, wherein the first portion has a U-shaped cross section.

4. The semiconductor structure according to claim 2, wherein a central portion of the first portion has a convex top surface and a flat bottom surface.

5. The semiconductor structure according to claim 2, wherein the second portion has a flat bottom surface and a flat top surface.

6. The semiconductor structure according to claim 2, further comprising a hybrid contact located on the second portion of the aluminum circuit layer, wherein the hybrid contact is made of copper.

7. The semiconductor structure according to claim 6, wherein the hybrid contact comprises a contact post and a contact pad stacked from bottom to top, wherein an area of the contact pad is larger than an area of the contact post.

8. The semiconductor structure according to claim 1, wherein among the plurality of metal circuit layers, other metal circuit layers below the aluminum circuit layer are made of copper.

9. A method for forming a semiconductor structure, comprising:
forming a plurality of metal circuit layers and stacked with each other, wherein the plurality of metal circuit layers comprises an aluminum circuit layer, which is located at the position closest to a surface in the plurality of circuit layers, wherein the aluminum circuit layer is made of aluminum, and the aluminum circuit layer comprises a concave portion.

10. The method for forming a semiconductor structure according to claim 9, wherein the aluminum circuit layer comprises a first portion and a second portion, wherein a bottom surface of the first portion is lower than a bottom surface of the second portion, and the concave portion is located in the first portion.

11. The method for forming a semiconductor structure according to claim 10, wherein the first portion has a U-shaped cross section.

12. The method for forming a semiconductor structure according to claim 10, wherein a central portion of the first portion has a convex top surface and a flat bottom surface.

13. The method for forming a semiconductor structure according to claim 10, wherein the second portion has a flat bottom surface and a flat top surface.

14. The method for forming a semiconductor structure according to claim 10, further comprising forming a hybrid contact on the second portion of the aluminum circuit layer, wherein the hybrid contact is made of copper.

15. The method for forming a semiconductor structure according to claim 14, wherein the hybrid contact comprises a contact post and a contact pad stacked from bottom to top, wherein an area of the contact pad is larger than an area of the contact post.

16. The method for forming a semiconductor structure according to claim 14, wherein after forming an aluminum circuit layer, the aluminum circuit layer is located on a top surface of the semiconductor structure, and further comprises a test step to test whether an electrical value of the plurality of metal circuit layer meets a preset requirement.

17. The method for forming a semiconductor structure according to claim 16, wherein if the electrical value of the plurality of metal circuit layer meets the preset requirement, the hybrid contact is continuously formed.

18. The method for forming a semiconductor structure according to claim 16, wherein if the electrical value of the plurality of metal circuit layer does not meet the preset requirements, the semiconductor structure is discarded and a process adjustment step is performed.

19. The method for forming a semiconductor structure according to claim 9, wherein among the plurality of metal circuit layers, other metal circuit layers below the aluminum circuit layer are made of copper.
